(19) United States
(12) Patent Application Publication
(10) Pub. No.: US 2025/0389674 A1
(43) Pub. Date: Dec. 25, 2025

(54) Method of Quality Inspection of a Joint of a Power Cable

(71) Applicant: NKT HV Cables AB, Lyckeby (SE)

(72) Inventors: Kristian Gustafsson, Karlskrona (SE); Amirhossein Abbasi, Karlskrona (SE)

(21) Appl. No.: 18/877,568

(22) PCT Filed: May 10, 2023
(86) PCT No.: PCT/EP2023/062485

§ 371 Date: Dec. 20, 2024

(30) Foreign Application Priority Data
Jun. 22, 2022 (EP) 22180574.0

(51) Int. Cl. G01N 21/952; G01B 11/06; G01B 11/24; H02G 1/14; H02G 1/16

(52) U.S. Cl. CPC G01N 21/952; G01B 11/06; G01B 11/24; H02G 1/14; H02G 1/16

(57) ABSTRACT

A method of performing a quality inspection of a vulcanized joint of a power cable during manufacturing of the vulcanized joint, the method comprising: a) obtaining, from a laser scanner, measurements of an outer surface of an inner semiconducting layer provided over a conductor joint which joints conductors of two power cable sections, and of a transition area between the outer surface and outer surfaces of a respective inner semiconducting layer of the two power cable sections, b) obtaining, from a laser scanner, measurements of an outer surface of a tapering section of an insulation layer arranged around a respective one of the inner semiconducting layers of the two cable sections, c) processing the measurements obtained in step a) and in step b), the processing involving generating one or a respective 3-d model of the outer surfaces and evaluating an outer surface quality of the outer surfaces based on the one or more 3-d models, d) presenting a conclusion regarding surface quality based on the evaluation, e) obtaining, from a laser scanner, measurements of an outer surface of a joint insulation arranged around the inner semiconducting layer that is provided over the conductor joint, the joint insulation having been provided over the inner semiconducting layer provided around the conductor joint after step d), and f) processing measurements obtained from the laser scanner in step e), the processing involving determining an insulation thickness or an outer diameter of the joint insulation, and g1) presenting the insulation thickness or outer diameter, and/or, g2) evaluating the insulation thickness or outer diameter, and presenting a conclusion regarding the insultation thickness or outer diameter based on the comparison.

### TECHNICAL FIELD

The present disclosure generally relates to power cables.

### BACKGROUND

High voltage (HV) power cables generally include, from inside to outside: a conductor, an insulation system, and an outer sheath. In particular, the insulation system comprises an inner semiconducting layer, an insulating layer arranged around the inner semiconducting layer, and an outer semiconducting layer arranged around the insulating layer.

It is required to mechanically process an HV power cable when for example making a joint. The processing includes peeling off the outer semiconducting layer and may include subsequent grinding of the insulating layer, depending on the voltage rating of the cable.

It is important that the processed layers have an even surface structure. A conventional method of inspecting the processing result is a manual inspection of the processed layers relying on tactile feedback, by sliding a finger over the processed area. The quality of a manual inspection depends on the experience of the inspecting person.

Other conventional methods include measurement with a slide gauge or with a diameter tape. In general, conventional methods of inspecting the insulation of an HV cable after processing have limitations as to their reliability and replicability.

EP 3 901 571 A1 discloses a system and a method for determining the quality of a surface of a high voltage cable end. The method comprises moving a non-contact surface scanner about the cable end, measuring distance to the surface over the area of the surface by sequentially measuring a plurality of sub-areas of the area of the surface, creating a continuous 3D surface geometry measurement of the cable end and comparing, using the continuous 3D surface geometry measurement with at least one surface geometry acceptance threshold determining the quality of the surface of the high voltage cable end.

### SUMMARY

An object of the present disclosure is to provide a method of performing quality inspection of a power cable which solves or at least mitigates the problems of the prior art.

There is hence according to a first aspect of the present disclosure provided a method of performing a quality inspection of a vulcanized joint of a power cable during manufacturing of the vulcanized joint, the method comprising: a) obtaining, from a laser scanner, measurements of an outer surface of an inner semiconducting layer provided over a conductor joint which joints conductors of two power cable sections, and of a transition area between the outer surface and outer surfaces of a respective inner semiconducting layer of the two power cable sections, b) obtaining, from a laser scanner, measurements of an outer surface of a tapering section of an insulation layer arranged around a respective one of the inner semiconducting layers of the two cable sections, c) processing the measurements obtained in step a) and in step b), the processing involving generating one or a respective 3-d model of the outer surfaces and evaluating an outer surface quality of the outer surfaces based on the one or more 3-d models, d) presenting a conclusion regarding surface quality based on the evaluation, e) obtaining, from a laser scanner, measurements of an outer surface of a joint insulation arranged around the inner semiconducting layer that is provided over the conductor joint, the joint insulation having been provided over the inner semiconducting layer provided around the conductor joint after step d), and f) processing the measurements obtained from the laser scanner in step e), the processing involving determining an insulation thickness or an outer diameter of the joint insulation, and g1) presenting the insulation thickness or outer diameter, and/or, g2) evaluating the insulation thickness or outer diameter, and presenting a conclusion regarding the insultation thickness or outer diameter based on the comparison.

The quality of all processed layers of a vulcanised joint may thus be determined using an automated process which is not dependent on the experience of the personnel carrying out the jointing. A vulcanised joint of the required quality can thus be built without having to rely heavily on human experience.

The processing in step c) may involve determining an angle or slope of the tapering sections. Step d) may in this case involve presenting the angle or slope of the tapering sections. To have the correct angle/slope of the tapering sections, or cones, is of importance when carrying out the jointing.

According to one embodiment step f) involves generating a 3-d model of the outer surface of the joint insulation.

According to one embodiment the evaluating in step c) involves assessing roundness and surface texture of the outer surfaces.

According to one embodiment the evaluating in step c) involves comparing each 3-d model with a respective reference 3-d model.

According to one embodiment the evaluating in step g2) involves comparing the insulation thickness or the outer diameter with a reference.

According to one embodiment the reference is a 3d model of the joint insulation.

According to one embodiment the laser scanner is a 3d laser scanner.

According to a second aspect of the present disclosure there is provided a quality inspection system comprising: processing circuitry, a laser scanner configured to send measurements to the processing circuitry, and a storage medium comprising computer code which when executed by the processing circuitry causes the quality inspection system to carry out the method of the first aspect.

There is according to a third aspect of the present disclosure provided a method of making a vulcanized joint of a power cable utilising the quality inspection system of the second aspect, the method comprising: A) making a conductor joint between two conductor ends of respective power cable lengths, to form a single power cable with two power cable sections separated by the conductor joint, B) making a respective insulation layer of the two power cable sections tapering, C) providing an inner semiconducting layer around the conductor joint, the inner semiconducting layer contacting respective inner semiconducting layers of the power cable sections, D) making a quality inspection of the outer surface of the inner semiconducting layers and of the tapering outer surfaces of the insulation layers of the two power cable sections using the quality inspection system, wherein if the outcome of the quality inspection is a fail, the method comprises E) mechanically processing the outer surface(s) of the inner semiconducting layer(s) and/or the tapering outer surfaces, and repeating step D), wherein if the outcome of the quality inspection is a pass, the method comprises F) making a joint insulation over the inner semiconducting layer provided around the conductor joint, the joint insulation contacting the tapering outer surfaces, G) making a quality inspection of the joint insulation using the quality inspection system to determine an outer diameter or insulation thickness of the joint insulation, wherein if the outcome of the quality inspection in step G) is a fail, the method comprises H) mechanically processing the outer surface of the joint insulation, and repeating steps G) and H) until the outcome of the quality inspection in step G) is a pass.

Generally, all terms used in the claims are to be interpreted according to their ordinary meaning in the technical field, unless explicitly defined otherwise herein. All references to “a/an/the element, apparatus, component, means”, etc. are to be interpreted openly as referring to at least one instance of the element, apparatus, component, means, etc., unless explicitly stated otherwise.

### BRIEF DESCRIPTION OF THE DRAWINGS

The specific embodiments of the inventive concept will now be described, by way of example, with reference to the accompanying drawings, in which:

FIG. 1 is a block diagram of a quality inspection system;

FIG. 2 schematically shows a laser scanner scanning a vulcanized joint, during manufacturing of the vulcanised joint, shown in a longitudinal section;

FIG. 3 schematically shows a laser scanner scanning a vulcanized joint shown in a longitudinal section; and

FIG. 4 is a flowchart of a method of making a vulcanised joint, including performing quality inspection of the vulcanized joint.

### DETAILED DESCRIPTION

The inventive concept will now be described more fully hereinafter with reference to the accompanying drawings, in which exemplifying embodiments are shown. The inventive concept may, however, be embodied in many different forms and should not be construed as limited to the embodiments set forth herein; rather, these embodiments are provided by way of example so that this disclosure will be thorough and complete, and will fully convey the scope of the inventive concept to those skilled in the art. Like numbers refer to like elements throughout the description.

FIG. 1 shows a block diagram of an example of a quality inspection system 1. The quality inspection system 1 is configured to provide a quality inspection of insulation system layers of a vulcanized joint of a power cable, during the manufacturing process of the vulcanised joint.

The power cable may be an underground power cable or a submarine power cable. The power cable may be an AC or a DC power cable. The power cable may be a medium voltage or high voltage power cable. The quality inspection system 1 comprises a laser scanner 3. The laser scanner may be a 3-d laser scanner. The laser scanner 3 may be handheld. Thus, a user may hold the laser scanner 3 in their hand(s) when scanning an object such as a vulcanized joint. Alternatively, the laser scanner 3 may be mounted to a structure which enables axial movement along a power cable and/or circumferential movement in a circumferential direction around a power cable.

The quality inspection system 1 comprises processing circuitry 5 connected to the laser scanner 3. Further, the quality inspection system 1 may comprise a storage medium 7 configured to communicate with the processing circuitry 5.

The processing circuitry 5 and/or the storage medium 7 may be integrated with the laser scanner 3, or one or both of the processing circuitry 5 and the storage medium 7 may be arranged separately from the laser scanner 3.

The processing circuitry 5 may for example use any combination of one or more of a suitable central processing unit (CPU), multiprocessor, microcontroller, digital signal processor (DSP), application specific integrated circuit (ASIC), field programmable gate arrays (FPGA) etc., capable of executing any herein disclosed operations concerning quality inspection of a vulcanized joint of a power cable.

The storage medium 7 may for example be embodied as a memory, such as a random access memory (RAM), a read-only memory (ROM), an erasable programmable read-only memory (EPROM), or an electrically erasable programmable read-only memory (EEPROM) and more particularly as a non-volatile storage medium of a device in an external memory such as a USB (Universal Serial Bus) memory or a Flash memory, such as a compact Flash memory.

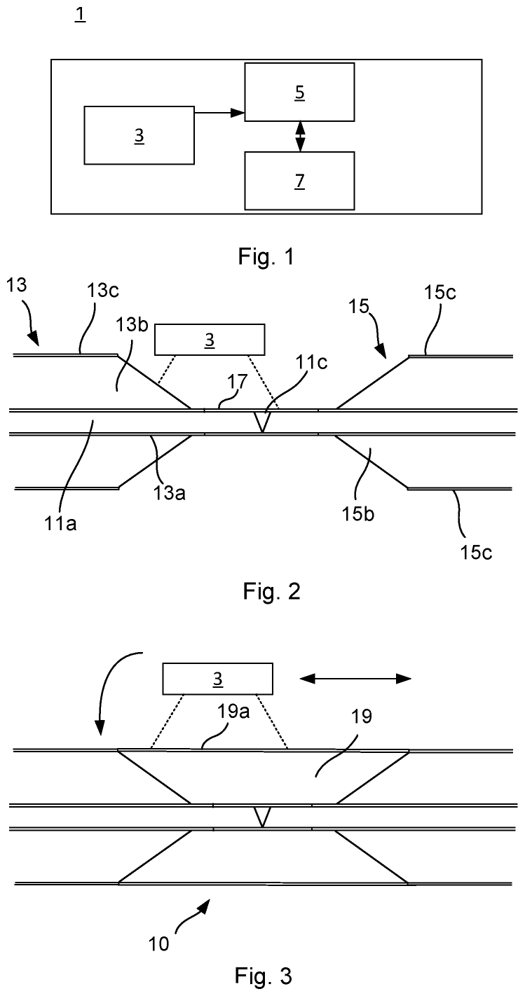

A method of making a vulcanised joint 10, shown in FIG. 3, will now be described with reference to FIGS. 2-4. The making of the vulcanised joint 10 typically involves manual labour steps carried out by factory personnel in a cable factory, or by field personnel for example on a cable laying vessel, and quality inspection carried out during the making of the vulcanised joint 10 involves use of the quality inspection system 1, for example operated by factory/field personnel.

FIG. 2 schematically shows the process of making a vulcanized joint using the quality inspection system 1. A vulcanized joint is a flexible joint that usually is made in the factory but can also be made in the field, for example on a cable laying vessel. The vulcanized joint 10 joins two power cable sections, which thus form a single power cable. The power cable sections comprise a respective conductor 11a, 11b, which are joined by means of a conductor joint 11c. Further, each power cable length comprises a respective insulation system 13, 15. Each insulation system 13, 15 comprises an inner semiconducting layer 13a, 15a arranged around the respective conductor 11a, 11b, an insulation layer 13b, 15b arranged around the inner semiconducting layer 13a, 15a, and an outer semiconducting layer 13c, 15c arranged the insulation layer 13b, 15b.

The inner semiconducting layer 13a, 15a may for example comprise crosslinked polyethylene (XLPE). The insulation layer 13b, 15b may comprise XLPE. The outer semiconducting layer 13c, 15c may comprise XLPE.

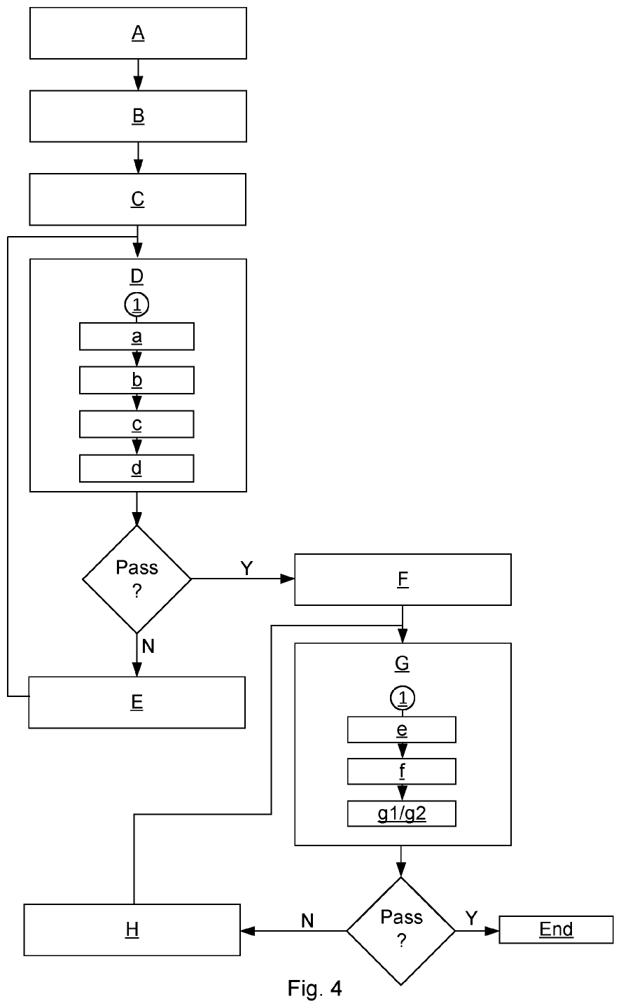

Before jointing, the cable ends of two power cable lengths are processed by removing the insulation system 13, 15 to expose the conductors 11a and 11b. The conductors 11a and 11b are then in a step A), shown in FIG. 4, joined to form the conductor joint 11c, shown in FIG. 2. The jointing may be made by means of welding, for example to make a V-shaped weld.

In a step B) the two facing ends of the respective insulation layer 13b and 15b are made tapering such that they taper towards each other. The facing ends of the insulation layers 13b and 15b are made tapering by mechanical processing.

In a step C) an inner semiconducting layer 17 is arranged over the conductor joint 11c and an entire naked section of the conductors 11a and 11b after their joining. The inner semiconducting layer 17 is arranged to overlap the two inner semiconducting layers 13a and 15a of the two jointed power cable lengths, which now are power cable sections of the jointed power cable. The region of overlap between the inner semiconducting layer 17 and the two inner semiconducting layers 13a and 15a are transition areas of the common inner semiconducting layer of the power cable formed by the two jointed power cable lengths.

The inner semiconducting layer 17 may for example be made by winding layers of tape around the conductor joint 11c and the naked sections of the conductors 11a, and 11b, and heating the layers of tape to crosslink the inner semiconducting layer 17, or the inner semiconducting layer 17 may be done by injection moulding followed by further heating.

In a step D) a quality inspection of the outer surface of the inner semiconducting layers 17, 13a, 15a is made using the quality inspection system 1. The laser scanner 3, for example held by factory or field personnel, is moved over and scans the outer surface of the inner semiconducting layer 17 and the transition areas.

In a step a) measurements of the outer surface of the inner semiconducting layer 17 and the transition areas is obtained by the processing circuitry 5 during step D).

Further, in step D) the laser scanner 3 is moved over the tapering section of each of the insulation layers 13b and 15b, scanning the outer surface of the tapering sections.

In a step b) the processing circuitry 5 obtains the measurements of the outer surfaces of the tapering sections, from the laser scanner 3.

In a step c) the measurements obtained in step a) and in step b) are processed by the processing circuitry 5.

The processing involving generating a single or a respective 3-d model of the outer surfaces and evaluating an outer surface quality of the outer surfaces based on the one or more 3-d models. Thus, according to one example measurements from each outer surface region may be used to generate a respective 3-d model, each for example modelling a respective transition area, and the outer surface of the inner semiconducting layer 17 between the transition areas, or a single 3-d model may be generated, modelling all the scanned outer surfaces.

The evaluating in step c) may involve comparing each 3-d model with a respective reference 3-d model and determining whether the surface quality passes or fails predefined criteria. The evaluating in step c) may for example involve assessing the roundness of the outer surfaces, measured e.g., along their perimeter, and/or assessing a surface texture, such as smoothness and irregularities, of the outer surfaces. Roundness and surface texture may for example be evaluated by comparing determined parameters with respective acceptable thresholds or a degree of deviation from the reference 3-d model(s).

In a step d) a conclusion regarding surface quality based on the evaluation is presented by the quality inspection system 1. The presentation may be visual, for example on a display, and/or aural, e.g., by making a predefined sound if the surface quality passes the predefined criteria or fails the predefined criteria.

If the outcome of the quality inspection of the outer surfaces of steps c)-d) is a fail, the method of making the vulcanised joint comprises a step E) mechanically processing the outer surface(s) of the inner semiconducting layer(s), transition areas, and/or the tapering outer surfaces, and repeating the quality inspection of these outer surfaces after the mechanical processing.

Once the outcome of the quality inspection is a pass, the method of making the vulcanised joint comprises a step of F) making a joint insulation 19 over the inner semiconducting layer 17 provided around the conductor joint 11c. The joint insulation 19 extends between and contacts the tapering outer surfaces. The joint insulation 19 may for example be done by winding layers of an insulation tape around the inner semiconducting layer 17 and subjecting the insulation tape to heat treatment for crosslinking, or it could be made by means of injection moulding followed by heat treatment.

After step F), a step G) of making a quality inspection of the joint insulation 19 is made e.g., by factory personnel or field personnel, using the quality inspection system 1, to determine the outer diameter or insulation thickness of the joint insulation 19.

In a step e) measurements of an outer surface 19a of the joint insulation 19 are obtained from the laser scanner 3, which scans the outer surface 19a of the joint insulation 19 during step G).

In a step f) carried out by the quality inspection system 1, the measurements obtained from the laser scanner 3 in step e) are processed by the processing circuitry 5. The processing involves determining an insulation thickness or an outer diameter of the joint insulation 19.

Further, in a step g1) carried out by the quality inspection system 1, the insulation thickness or outer diameter of the joint insulation 19 is presented.

The presenting may be on a display of the quality inspection system 1 and/or it may be aural. In a step g2), which may be carried out in addition to step g1) or as an alternative to step g1) by the quality inspection system 1, the insulation thickness or outer diameter is evaluated, and a conclusion regarding the insultation thickness or outer diameter based on the comparison is presented. The presenting may be on a display of the quality inspection system 1 and/or it may be aural.

The evaluating in step g2) may involve comparing the insulation thickness or the outer diameter with a reference. The reference may be a 3d model of the joint insulation 19.

If the outcome of the quality inspection in step G) is a fail, the method comprises H) mechanically processing the outer surface 19a of the joint insulation 19, and repeating steps G) and H) until the outcome of the quality inspection in step G) is a pass.

The inventive concept has mainly been described above with reference to a few examples. However, as is readily appreciated by a person skilled in the art, other embodiments than the ones disclosed above are equally possible within the scope of the inventive concept, as defined by the appended claims.

1. A method of performing a quality inspection of a vulcanized joint of a power cable during manufacturing of the vulcanized joint, the method comprising:
a) obtaining, from a laser scanner, measurements of an outer surface of an inner semiconducting layer provided over a conductor joint which joints conductors of two power cable sections, and of a transition area between the outer surface and outer surfaces of a respective inner semiconducting layer of the two power cable sections,
b) obtaining, from a laser scanner, measurements of an outer surface of a tapering section of an insulation layer arranged around a respective one of the inner semiconducting layers of the two cable sections,
c) processing the measurements obtained in step a) and in step b), the processing involving generating one or a respective 3D model of the outer surfaces and evaluating an outer surface quality of the outer surfaces based on the one or more 3D models,
d) presenting a conclusion regarding surface quality based on the evaluation,
e) obtaining, from a laser scanner, measurements of an outer surface of a joint insulation arranged around the inner semiconducting layer that is provided over the conductor joint, the joint insulation having been provided over the inner semiconducting layer provided around the conductor joint after step d), and
f) processing the measurements obtained from the laser scanner in step e), the processing involving determining an insulation thickness or an outer diameter of the joint insulation, and
g1) presenting the insulation thickness or outer diameter, and/or,
g2) evaluating the insulation thickness or outer diameter, and presenting a conclusion regarding the insultation thickness or outer diameter based on the comparison.

2. The method as claimed in claim 1, wherein step f) involves generating a 3D model of the outer surface of the joint insulation.

3. The method as claimed in claim 1, wherein the evaluating in step c) involves assessing roundness and surface texture of the outer surfaces.

4. The method as claimed in claim 1, wherein the evaluating in step c) involves comparing each 3D model with a respective reference 3D model.

5. The method as claimed in claim 1, wherein the evaluating in step g2) involves comparing the insulation thickness or the outer diameter with a reference.

6. The method as claimed in claim 5, wherein the reference is a 3D model of the joint insulation.

7. The method as claimed in claim 1, wherein the laser scanner is a 3D laser scanner.

8. A quality inspection system comprising:
processing circuitry,
a laser scanner configured to send measurements to the processing circuitry, and
a storage medium having computer code which when executed by the processing circuitry causes the quality inspection system to carry out the method of performing a quality inspection of a vulcanized joint of a power cable during manufacturing of the vulcanized joint, the method including:
a) obtaining, from a laser scanner, measurements of an outer surface of an inner semiconducting layer provided over a conductor joint which joints conductors of two power cable sections, and of a transition area between the outer surface and outer surfaces of a respective inner semiconducting layer of the two power cable sections,
b) obtaining, from a laser scanner, measurements of an outer surface of a tapering section of an insulation layer arranged around a respective one of the inner semiconducting layers of the two cable sections,
c) processing the measurements obtained in step a) and in step b), the processing involving generating one or a respective 3D model of the outer surfaces and evaluating an outer surface quality of the outer surfaces based on the one or more 3D models,
d) presenting a conclusion regarding surface quality based on the evaluation,
e) obtaining, from a laser scanner, measurements of an outer surface of a joint insulation arranged around the inner semiconducting layer that is provided over the conductor joint, the joint insulation having been provided over the inner semiconducting layer provided around the conductor joint after step d), and
f) processing the measurements obtained from the laser scanner in step e), the processing involving determining an insulation thickness or an outer diameter of the joint insulation, and
g1) presenting the insulation thickness or outer diameter, and/or,
g2) evaluating the insulation thickness or outer diameter, and presenting a conclusion regarding the insulation thickness or outer diameter based on the comparison.

9. A method of making a vulcanized joint of a power cable utilising the quality inspection system comprising:
A) making a conductor joint between two conductor ends of respective power cable lengths, to form a single power cable with two power cable sections separated by the conductor joint,
B) making a respective insulation layer of the two power cable sections tapering,
C) providing an inner semiconducting layer around the conductor joint, the inner semiconducting layer contacting respective inner semiconducting layers of the power cable sections,
D) making a quality inspection of the outer surface of the inner semiconducting layers and of the tapering outer surfaces of the insulation layers of the two power cable sections using the quality inspection system,
wherein if the outcome of the quality inspection is a fail, the method includes: E) mechanically processing the outer surface(s) of the inner semiconducting layer(s) and/or the tapering outer surfaces, and repeating step D),
wherein if the outcome of the quality inspection is a pass, the method includes: F) making a joint insulation over the inner semiconducting layer provided around the conductor joint, the joint insulation contacting the tapering outer surfaces,
G) making a quality inspection of the joint insulation using the quality inspection system to determine an outer diameter or insulation thickness of the joint insulation,
wherein if the outcome of the quality inspection in step G) is a fail, the method includes: H) mechanically processing the outer surface of the joint insulation, and repeating steps G) and H) until the outcome of the quality inspection in step G) is a pass.

10. The method as claimed in claim 2, wherein the evaluating in step c) involves assessing roundness and surface texture of the outer surfaces.

11. The method as claimed in claim 2, wherein the evaluating in step c) involves comparing each 3D model with a respective reference 3D model.

12. The method as claimed in claim 2, wherein the evaluating in step g2) involves comparing the insulation thickness or the outer diameter with a reference.

13. The method as claimed in claim 2, wherein the laser scanner is a 3D laser scanner.
